(19) United States
(12) Patent Application Publication
(10) Pub. No.: US 2005/0112281 A1
(43) Pub. Date: May 26, 2005

(54) Growth of dilute nitride compounds

(76) Inventor: Rajaram Bhat, Painted Post, NY (US)

Correspondence Address: CORNING INCORPORATED, SP-TI-3-1, CORNING, NY, 14831, US

(21) Appl. No.: 10/718,744

(22) Filed: Nov. 21, 2003

(51) Int. Cl. C23C 16/00

(52) U.S. Cl. 427/248.1

(57) ABSTRACT

A method for growing a dilute nitride includes placing a III-V substrate 120 in a chemical reaction chamber 125. The III-V substrate 120 is heated to a predetermined temperature in a range about 550-700 degree C. in an atmosphere including a Group V element gas or vapor 187. Vapors of at least one Group III element organometallic compound 135, 150, 162 are flowed into the chemical reaction chamber for initiating an epitaxial growth. Vapors of a Group III element containing compound 172 wherein at least one Group III element is covalently bonded with nitrogen (N) are also flowed to grow dilute nitride films on the III-V substrate inside the chamber 125.

### BACKGROUND OF THE INVENTION

1. Field of the Invention

The present invention relates generally to III-V compounds such as dilute nitride compounds, and particularly to the epitaxial growth of a III-V compound where nitrogen is at least one of the Group V elements.

2. Technical Background

High quality epitaxial growth of dilute nitride III-V compounds, such as GaInAsN, using organometallic chemical vapor deposition or epitaxy (OMCVD, OMVPE, MOCVD, or MOVPE) is challenging because the growth has to be done at low temperatures to incorporate nitrogen. OMCVD is the most general term and includes OMVPE, MOCVD, and MOVPE but others sometime use other names, such as MOCVD. In the growth of these compounds by OMCVD, the incorporation of nitrogen (N) as the Group V element is very difficult in the presence of the Group III element, indium (In); except when nitrogen trifluoride (NF₃) is used as the nitrogen source. Prior efforts required very low growth temperatures and high fluxes of the N compound. The low growth temperature leads to poor material quality. The nitrogen incorporation problem with indium does not exist in an alternate growth technique—molecular beam epitaxy (MBE). However, even with MBE, it is not possible to grow GaInAsN and other dilute nitrides at high temperatures (600-700° C.). OMCVD is known to be the preferred growth technique for high volume production. GaInAsN/GaAs based lasers are important for 1.3 and 1.55 micron edge emitting and surface emitting lasers. To date the results for 1.3 micron lasers are promising but the current growth techniques do not produce a high enough material quality to enable good 1.55 micron lasers and even high performing and reliable 1.3 micron lasers. The ability to do long wavelength lasers on GaAs, rather than on InP, is important for making surface emitting lasers (VCSELs), since high quality GaAs/AlAs Bragg reflectors can be easily fabricated on the common GaAs substrate.

Therefore, there is a need to improve the quality of high volume epitaxial growth of dilute nitride III-V compounds.

### SUMMARY OF THE INVENTION

One aspect of the invention is a method for growing a dilute nitride by placing a III-V substrate in a chemical reaction chamber. The III-V substrate is heated to a predetermined temperature in a range about 550-700 degree C. in an atmosphere including a Group V element gas or vapor. Vapors of at least one Group III element organometallic compound are flowed into the chemical reaction chamber for initiating an epitaxial growth in the presence of the same or at least one different Group V element gas or vapor. Vapors of a Group III element containing compound wherein at least one Group III element is already covalently bonded with the Group V element nitrogen (N) are also flowed to grow dilute nitride films on the III-V substrate inside the chamber.

In another aspect, the present invention includes keeping amount of the Group III element containing compound, with the Group III element covalently bonded to N, and the at least one Group III element organometallic compound at a raw material volume ratio of less than 15% for the Group III element containing compound to the 85% of the volume of the at least one Group III element organometallic compound.

Additional features and advantages of the invention will be set forth in the detailed description which follows, and in part will be readily apparent to those skilled in the art from that description or recognized by practicing the invention as described herein, including the detailed description which follows, the claims, as well as the appended drawings.

It is to be understood that both the foregoing general description and the following detailed description present embodiments of the invention, and are intended to provide an overview or framework for understanding the nature and character of the invention as it is claimed. The accompanying drawings are included to provide a further understanding of the invention, and are incorporated into and constitute a part of this specification. The drawings illustrate various embodiments of the invention, and together with the description serve to explain the principles and operations of the invention.

### BRIEF DESCRIPTION OF THE DRAWINGS

FIG. 1 is a simplified diagram of a chemical vapor depositon system, such as for OMCVD, MOCVD, OMVPE, or MOVPE, according to the present invention.

### DETAILED DESCRIPTION OF THE PREFERRED EMBODIMENTS

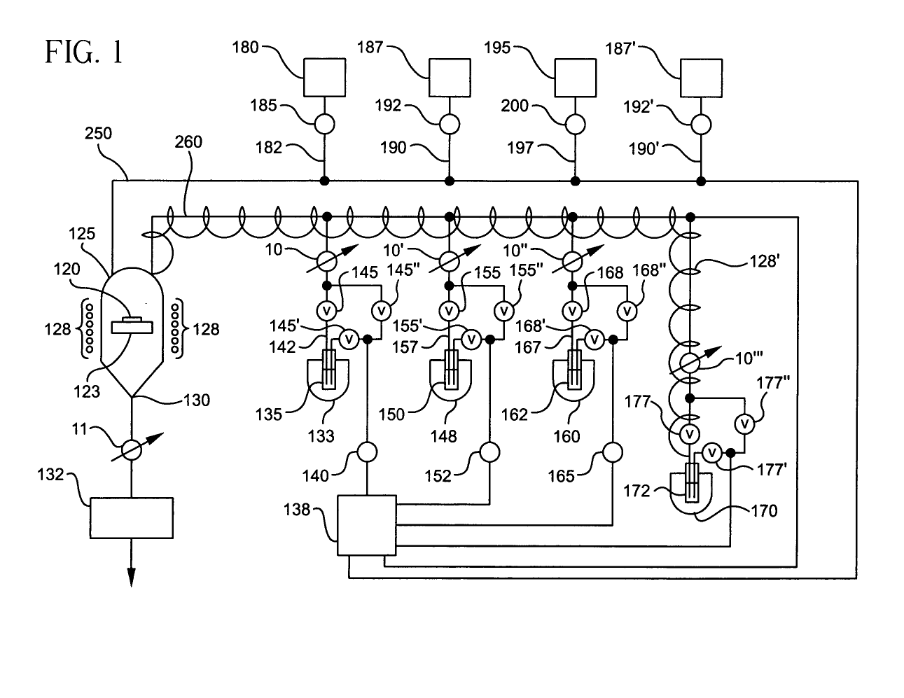

Reference will now be made in detail to the present preferred embodiment of the invention, an example of which is illustrated in the accompanying drawing. Whenever possible, the same, primed, or double primed reference numerals will be used throughout the drawing to refer to the same or like parts. One embodiment of the chemical reaction chamber 125 of the present invention is shown as a metal organic chemical vapor deposition (MOCVD or OMCVD) chamber in FIG. 1, but is designated generally throughout by the reference numeral 125 to refer to an equivalent chemical reaction chamber for other types of systems, such as chemical beam epitaxy (CBE) chamber or metal-organic molecular beam epitaxy (MOMBE) chamber.

As embodied herein and depicted in FIG. 1, a method for growing a dilute nitride includes placing a III-V substrate 120 in a chemical reaction chamber 125. The III-V substrate 120 is heated to a predetermined temperature in a range about 550-700 degree C. in an atmosphere including a first Group V element gas or vapor 187. Typically, vapors of at least one Group III element organometallic compound 135, 150, 162 are flowed into the chemical reaction chamber for initiating the growth of a III-V buffer layer, in the presence of the same or different Group V element gas or vapor. However, such buffer layers are not essential. The buffer layer growth is followed by the growth of a dilute nitride layer by flowing into the chamber 125 vapors of at least one Group III organometallic compound 135, 150, 162 and vapors of a Group III element containing compound 172 wherein at least one Group III element is covalently bonded with nitrogen (N) in the presence of the same or different group V element gas or vapor as in the previous step. If the group V gas or vapor required in a step is different from that used in a previous step, then the new Group V element gas or vapor can be exchanged for the one used in the previous step either simultaneously with the commencement of the new step or up to 10 seconds before. In addition, more than one Group V element gas or vapor may be used in the heating and growth steps.

After the III-V substrate is cooled-down, the dilute nitride film growth would be grown on top of the substrate. Optionally, additional steps include providing an overpressure of a second Group V element gas or vapor 187′ during the growth (flowing vapor) step and the cooling-down step. The first and second Group V element gas or vapor can be the same or different material, depending on the suitability with the substrate or the film grown on the substrate. A nitrogen overpressure 195 could also be optionally provided during the flowing vapor steps and the cooling-down step.

Referring to FIG. 1, an MOCVD system that can be used to grow the III-V dilute nitride semiconductor compound materials on a selected substrate 120 is shown. The substrate 120 is disposed on a graphite susceptor 123 for heating. Without limitations, the substrate 120 can be a wafer made from GaAs, GaP, InAs, or InP.

As will be discussed later, the heating is higher than is typical for a low pressure metal organic chemical vapor deposition (LP-MOCVD) of dilute nitrides, in order to encourage sufficient nitrogen (N) concentration in the epitaxial material, and the pressure can range from ultra-high to ultra-low pressure in the chamber 125 as controlled by a throttle 11 to exhaust excess gas. An exemplary range of the pressure in the chamber 125 as controlled by the throttle valve 11 would be from below atmosphere to much, much higher than atmosphere, such as 1 Torr to 10 atm.

The substrate 120 and susceptor 123 are housed in a quartz reactor tube 125 which is ringed by a set of conductive coils 128. A radio frequency alternating current is adjustably applied to the coils 128 to produce heat in the susceptor 123, thereby heating the substrate 120 to a desired temperature. As is known, other sources of heat could be infrared (IR) or resistive heating. A reaction chamber made from other materials, such as stainless steel, can also be employed.

Connected to an outlet 130 of the tube 125 is a vacuum pump 132 which is used to evacuate the tube 125 of gases as is needed. The vacuum pump 132 is connected to the reaction chamber 125 via the throttle valve 11 in order to be able to control the pressure in the chamber 125.

Organometallic compounds that are used to introduce the Group III materials are contained in separate constant temperature baths. In a first constant temperature bath 133 is a bubbler of trimethylgallium (TMGa) 135 through which a carrier gas, such as hydrogen from a hydrogen gas or another carrier gas supply 138 is flowed, the flow controlled by a first flow regulator 140. As the hydrogen gas bubbles through the TMGa 135, the carrier gas becomes saturated with the organometallic vapor, the gaseous concentrations at saturation determined by the temperature within the first bath 133. A conduit 142 controlled by a first shut-off valve 145 connects the TMGa bubbler 135 with the reactor tube 125. By controlling the temperature in the first bath 133, the pressure of the TMGa bubbler 135 through a pressure controller 10, and the mass flow of hydrogen gas through the regulator 140, the mass flow of TMGa to the reactor tube 125 can be precisely controlled.

More flexible control can be obtained by diverting the original feedline into a second feedline with each split controlled by separate valves 145′. Valves 145 and 145′ are for shutting off the bubbler and valve 145″ is for bypassing the bubbler when it is not used. The pressure controller 10 is used to control the pressure in the bubbler for providing greater flexibility in the mass flow of the organometallic compound in the bubbler. These pressure controllers 10, extra valves 145′ and 145″, and diverted feedline can be present in all of the bubblers.

Hydrogen is only the most commonly used carrier gas for an MOCVD system. In other chemical reaction chambers, as known already, a carrier gas is not even needed. However, other examples of carrier gas include: hydrogen, nitrogen, argon, helium, hydrogen and nitrogen, hydrogen and argon, and hydrogen and helium. Even in MOCVD systems, it is not essential to have a carrier gas bubble or pass through a bubbler containing an organometallic compound.

A second constant temperature bath 148 houses a bubbler of trimethylaluminum (TMAl) 150 which is supplied with hydrogen gas from the hydrogen gas supply 138 at a rate controlled by a second flow regulator 152. In combination with the temperature of the second bath 148 and the pressure in the TMAl bubbler 150 through a pressure controller 10′, the flow of hydrogen gas through flow regulator 152 controls the flow of TMAl that can be allowed by a second shut-off valve 155 through conduit 157 to enter reactor tube 125.

Similarly, a third constant temperature bath 160 contains a bubbler of trimethylindium (TMIn) 162 which is provided with hydrogen gas at a rate controlled by a third flow regulator 165. Hydrogen gas saturated with TMIn can then be flowed to the reactor tube 125 via conduit 167, that flow switched on and off by shut-off valve 168, 168′ and bypass valve 168″.

One or more Group III element organometallic compounds as shown or not shown in FIG. 1 can be used to form the desired ternary or quaternary III-V material system. Alternative organometallic compounds may be used for the column or Group III element precursors. As an example, triethylgallium (TEGa) may be used in place of trimethylgallium (TMGa) as the gallium source. Similarly, alternative compounds exist for aluminum and indium which may be used for the growth of these III-V compounds. A non-inclusive list of Group III element organometallic compounds includes members such as Trimethylgallium, Triethylgallium, Trimethylindium, and Trimethylaluminum.

A fourth constant temperature bath 170 likewise contains a Group III element containing compound bubbler 172 which has hydrogen gas supplied to it at a rate determined by a fourth regulator 175. Flow to the reactor tube 125 of hydrogen gas saturated with the Group III element containing compound is then provided by conduit 176, controlled by a shut-off valves 177 and 177′ and bypass valve 177″. The Group III element containing compound is an organic or inorganic molecule, compound, or other material in which at least one Group III element is covalently bonded with nitrogen (N) to allow quality growth of dilute nitride films on the III-V substrate 120. Examples of the Group III element containing compounds include, without limiting: indium (In) as the Group III element covalently bonded with N to form a part of the Group III compound; gallium (Ga) as the Group III element covalently bonded with N to form a part of the Group III compound; aluminum (Al) as the Group III element covalently bonded with N to form a part of the Group III compound; indium (In) and gallium (Ga) as the Group III elements having at least In covalently bonded with N to form a part of the Group III compound; indium (In) and aluminum (Al) as the Group III elements having at least In covalently bonded with N to form a part of the Group III compound; gallium (Ga) and aluminum (Al) as the Group III elements having at least Al covalently bonded with N to form a part of the Group III compound; and gallium (Ga), indium (In), and aluminum (Al) as the Group III elements having at least In covalently bonded with N to form a part of the Group III compound.

By itself, these Group III element containing compounds with covalently bonded N are known and have been called single source precursors for GaN and InN, such as bis-azido dimethylaminopropyl gallium, mono-azido amino propyl indium, dimethylgallium amide, etc. A single source AlN precursor is also known. Single source AlN, GaN and InN precursors have been proposed for the growth of high bandgap nitrides such as binary III-V alloys GaN, AlN, and ternary III-V alloys AlGaN, etc. but not for the growth of quaternary or ternary dilute nitrides such as GaInAsN, GaInPN, GaAsN, InAsN, etc due to the large size of the precursor molecules. These molecules are called single source precursor for the growth of binary, ternary and quaternary nitride semiconductors because they already have the Group V element, nitrogen, incorporated with the Group III element as a 100% nitrogen source.

A single source precursor for dilute nitrides would contain both the Group III elements as well as the relevant Group V elements in a single molecule, with the III elements covalently bonded to the V elements. Such molecules are likely to be very large. The large molecule is likely to result in extremely low vapor pressure compounds. Furthermore, these large molecules would most likely have a poor surface mobility to yield high quality epitaxial growth.

Recently, a technique using nitrogen trifluoride (NF₃) has been disclosed for incorporating N in GaInAs wherein the N incorporation is weakly dependent on In content. However, this disclosed technique still requires low growth temperatures, since higher temperatures result in etching rather than growth.

The higher growth temperatures would produce superior materials having photoluminescence efficiency and minority carrier lifetime equivalent to material without the nitrogen incorporation. The higher quality nitrogen incorporated material would enable better devices and also likely produce good material for high performance and reliability of 1.3 and 1.55 micron lasers. In addition, the lack of interaction of N with In by their incorporation already in the precursor, allows easier control of materials growth, resulting in higher yield and lower cost devices. Moreover, the ability to control whether the N is bonded to mostly Ga or In allows the control of the properties of the quaternary alloy GaInAsN or other dilute nitrides.

To overcome the low quality limitations of a low temperature traditional MOCVD process for growing dilute nitrides, the teachings of the present invention thus uses the process controllability, such as through the pressure controls 10 and valves, of the traditional organometallic compounds, such as TrimethylGallium 135 and TrimethyIndium 162, as the major chemical species and add small amounts of single source precursors 172 for GaN and InN, such as bis-azido dimethylaminopropyl gallium, mono-azido amino propyl indium, dimethylgallium amide, etc., to introduce small percentages of nitrogen (N) to grow GaInAsN or other dilute nitrides.

The small amount of the single source precursors is about ten percent (10%) of the total volume where 90% would consist of the traditional organometallic compounds for growing the dilute nitride. At most, the amount of the Group III element containing compound would be kept at a raw material volume ratio of less than 15% for the Group III element containing compound as compared to the 85% of the volume of the at least one Group III element organometallic compound.

Since the N is already covalently bonded to Ga or In in the single source precursor, the GaN and InN components of GaInAsN are incorporated in proportion to the mole fractions of the single source precursors and no N incorporation inhibition due to the presence of In (or Ga or Al) is expected. This method also allows the N present in GaInAsN to be mostly preferentially bonded to either GaN or InN depending on whether only the Ga or the In precursor is added. Furthermore, the single source precursor requires a relatively high temperature, about 550 to 700° C., to deposit GaN or InN, allowing the growth of GaInAsN at relatively high temperatures.

The teachings of the present invention also apply to other dilute nitrides as well. The method can also be used to grow dilute nitrides containing Al by adding small amounts of a single source AlN precursor. Even in cases where there is no inhibition of N incorporation due to the presence of In, the single source precursor provides a way to grow the dilute nitrides at higher temperatures than would otherwise be possible.

One or more heating tape 128′ can be used to prevent condensation of the material from the bubbler in the gas line feeding the reaction chamber 125. This is particularly important when the bubbler is kept above room temperature, as is well known to practitioners in this field. Often the bath 176 containing the single source precursor will have to be kept well above room temperature, typically about 50-150° C.

As one possible example of the various types of dilute nitrides that can be grown, the As in GaInAsN is introduced through arsine, tertiarybutyl arsine or other inorganic or organometallic sources. The group V components used for the III-V crystal growth are supplied to the reaction tube 125 from separate containers. Examples of the Group V element gas or vapor are in the non-inclusive list having members such as arsine, tertiarybutylarsine, triethylarsine, alkyl arsine, phosphine, tertiarybutylphosphine, triethylphosphine, and alkyl phosphine.

A first plenum 180 contains phosphine (PH₃) gas which can be supplied to the reactor tube 125 via conduit 182 at rate controlled by a fifth mass flow regulator 185.

A second plenum 187 contains arsine (AsH₃) that can be flowed to the reactor tube 125 via conduit 190 at a rate controlled by a sixth flow regulator 192. Alternative sources may also be used for the column or Group V elements, phosphorus (P), arsenic (As) and antimony (Sb).

The same or a different Group V gas or vapor during the growth can be used as an overpressure of at least one Group V element gas or vapor during the heating step and the cooling-down step of the chemical reaction process for preventing decomposition of the substrate or the dilute nitride film, respectively. As is known, if the raw material of the Group V element is a gas, the same 187 or another plenum 187′ can be connected to the reactor tube 125 via conduit 190′ at a rate controlled by another flow regulator 192′. On the other hand, if the raw material of the Group V element is a solid or a liquid, another bubbler can be connected can be connected similar to the other bubblers for providing the Group V element vapor or gas, except that these bubblers would be connected to the Group V manifold 250 instead of the Group III manifold 260

The Group V material can be selected from a group consisting of arsine; tertiarybutylarsine, triethylarsine, or other alkyl arsines; phosphine, tertiarybutylphosphine; triethylphosphine; and alkyl phosphine. As is known, this is not a complete list of possible materials.

The selected Group V element can be different or the same during the vapor flowing growth step from the one selected during heat-up, depending on the material suitability with the growth film or the substrate. For example, if a form of arsenic (As) or phosphorous (P) was used as the overpressure and being the same material as the first Group V element gas or vapor, then a separate plenum is not needed to provide the Group V element gas or vapor during the vapor flowing growth steps and is provided by one or both of plenums 180 and 187. However, if a different raw material other than As or P is desired, such as antimony (Sb) containing gas, different than what is provided by the plenums 180 or 187, than an additional plenum 187′ is useful. Correspondingly, instead of a gas, if the raw material was a liquid for the different raw material other than As or P, such as antimony (Sb) containing vapor, than an additional bubbler (not shown) is useful. This bubbler would feed the Group V manifold 250.

Similarly, a nitrogen (N) overpressure can be provided during growth and cool-down, if necessary, by introducing N bearing precursors such as unsymmetrical dimethyl hydrazine, ammonia, etc for preventing decomposition of the dilute nitride film due to a departure of nitrogen. For use as a nitrogen overpressure during the flowing vapor steps, and the cooling-down step of the chemical reaction process, a third optional plenum 195 is filled with gaseous ammonia (NH₃) which can be flowed to reactor tube 125 via another conduit 197 at a rate controlled by a seventh regulator 200.

Alternatively, a nitrogen (N) overpressure can be supplied via an optional bubbler (not shown) connected like the other bubblers if the nitrogen source was a solid or a gas. If the nitrogen source was a gas, such as hydrazine (H₂NNH₂), then instead of being filled with ammonia, plenum 195 can be used. Even though hydrazine is known and has been used for dilute nitride and also for nitride growth, hydrazine is a dangerous explosive. Hence, more preferred materials that can be used can be selected from a group including at least dimethylhydrazine, ammonia, trimethylamine, alkylamine, and nitrogen trifluoride (NF₃).

In addition to the above described bubblers and plenums that contain the aforementioned group III and group V elements, other bubblers and plenums, which have been left out for ease of illustration, may be provided in a given MOCVD system, in order to provide inputs of other molecules. On the other hand, not all of the above delineated bubblers and plenums may be needed for a given application.

In order to form a crystal having desired concentrations of elements using this MOCVD system, gases are flowed into the reaction tube at precisely controlled rates and time periods. To accomplish this practical reactors are significantly more complex than shown in FIG. 1. The rates and time periods can vary considerably due to variations in sticking coefficients of the type III elements being adsorbed and other factors.

It will be apparent to those skilled in the art that various modifications and variations can be made to the present invention without departing from the spirit and scope of the invention, such as using a chemical beam epitaxy (CBE) chamber or metal-organic molecular beam epitaxy (MOMBE) chamber, instead of the MOCVD chamber shown, as the chemical reaction chamber. Thus it is intended that the present invention cover the modifications and variations of this invention provided they come within the scope of the appended claims and their equivalents.

1. A method for growing a dilute nitride film, the method comprising the steps of:
placing a III-V substrate in a chemical reaction chamber;
heating the III-V substrate to a predetermined temperature in a range about 550-700 degree C. in an atmosphere including a first Group V element gas or vapor matching the Group V element of the III-V substrate;
flowing vapors of at least one Group III element organometallic compound into the chemical reaction chamber for growing a III-V film in the presence of a second Group V element gas or vapor; and
flowing vapors into the chemical reaction chamber of a Group III element containing compound wherein at least one Group III element is covalently bonded with a Group V element nitrogen (N) to grow dilute nitride films on the III-V substrate.

2. The method of claim 1, wherein the placing step comprises placing the III-V substrate in an OMCVD chamber as the chemical reaction chamber; and
wherein the heating step comprises heating the III-V substrate in the atmosphere including a mixture of a carrier gas and the Group V element gas or vapor.

3. The method of claim 1, wherein the placing step comprises placing the III-V substrate in a CBE chamber or a MOMBE chamber as the chemical reaction chamber.

4. The method of claim 1, wherein the placing step comprises placing a GaAs substrate as the III-V substrate.

5. The method of claim 1, wherein the placing step comprises placing a GaP substrate as the III-V substrate.

6. The method of claim 1, wherein the placing step comprises placing an InAs substrate as the III-V substrate.

7. The method of claim 1, wherein the placing step comprises placing an InP substrate as the III-V substrate.

8. The method of claim 1, wherein the flowing vapors of the Group III element containing compound step comprises flowing vapors containing indium (In) as the Group III element covalently bonded with N to form a part of the Group III compound.

9. The method of claim 1, wherein the flowing vapors of the Group III element containing compound step comprises flowing vapors containing gallium (Ga) as the Group III element covalently bonded with N to form a part of the Group III compound.

10. The method of claim 1, wherein the flowing vapors of the Group III element containing compound step comprises flowing vapors containing aluminum (Al) as the Group III element covalently bonded with N to form a part of the Group III compound.

11. The method of claim 1, wherein the flowing vapors of the Group III element containing compound step comprises flowing vapors containing indium (In) and gallium (Ga) as the Group III elements having at least In covalently bonded with N to form a part of the Group III compound.

12. The method of claim 1, wherein the flowing vapors of the Group III element containing compound step comprises flowing vapors containing indium (In) and aluminum (Al) as the Group III elements having at least In covalently bonded with N to form a part of the Group III compound.

13. The method of claim 1, wherein the flowing vapors of the Group III element containing compound step comprises flowing vapors containing gallium (Ga) and aluminum (Al) as the Group III elements having at least Al covalently bonded with N to form a part of the Group III compound.

14. The method of claim 1, wherein the flowing vapors of the Group III element containing compound step comprises flowing vapors containing gallium (Ga), indium (In), and aluminum (Al) as the Group III elements having at least In covalently bonded with N to form a part of the Group III compound.

15. The method of claim 1, further comprising the step of cooling-down the III-V substrate having the dilute nitride film growth.

16. The method of claim 1, wherein the first and second Group V element gas or vapor contains at least one different Group V element.

17. The method of claim 1, wherein the first and second Group V element gas or vapor contains the same Group V element.

18. The method of claim 1, wherein the flowing vapors of the Group III element containing compound with the Group III element covalently bonded to N and the at least one Group III element organometallic compound step comprises flowing into the reaction chamber the vapors of the Group III element containing compound in a volume ratio of less than 15% to the 85% of the volume of the at least one Group III element organometallic compound.

19. A method for growing a III-V alloy containing at least 3 elements, the method comprising the steps of:
placing a GaAs substrate in an OMCVD chamber;
heating the GaAs substrate to a predetermined temperature in a range about 550-700 degree C. in a mixture of a first Group V element gas or vapor and a carrier gas, wherein the carrier gas is selected from a group consisting of hydrogen, nitrogen, argon, helium, hydrogen and nitrogen, hydrogen and argon, and hydrogen and helium;
flowing vapors of at least one Group III element organometallic compound into the OMCVD chamber for growing a III-V film in the presence of a second Group V element gas or vapor; and
flowing vapors into the OMCVD chamber of a Group III element containing compound wherein at least one Group III element is covalently bonded with a Group V element nitrogen (N) to grow dilute nitride films on the III-V substrate.

20. A method for growing a dilute nitride film, the method comprising the steps of:
placing a GaAs substrate in an OMCVD chamber;
heating the GaAs substrate to a predetermined temperature in a range about 550-700 degree C. in a mixture of hydrogen and a Group V element gas or vapor selected from a group consisting of arsine, tertiarybutylarsine, triethylarsine, alkyl arsine, phosphine, tertiarybutylphosphine, triethylphosphine, alkyl phosphine, and trimethylantimony;
flowing vapors of at least one Group III element organometallic compound containing a material selected from a group consisting of Trimethylgallium, Triethylgallium, Trimethylindium, Trimethylaluminum, and Trimethylboron in the presence of a second Group V element gas or vapor for growing a III-V film;
flowing vapors into the OMCVD chamber to grow dilute nitride films on the GaAs substrate of a Group III element containing compound, wherein at least one Group III element is covalently bonded with a Group V nitrogen (N), and the Group III element is selected from a group consisting of In, Ga, Al, Ga and Al, In and Ga, Ga and Al, and Ga, Al, and In;
cooling-down the GaAs substrate having the dilute nitride film growth in the presence of a third Group V element gas or vapor for preventing decomposition of the dilute nitride film; and
flowing vapors of nitrogen containing compound gas or vapor during the growth steps, and the cooling-down step using a material selected from a group consisting of dimethylhydrazine, ammonia, trimethylamine, alkylamine, and nitrogen trifluoride for preventing decomposition of the dilute nitride film due to a departure of nitrogen.
